(19) United States
(12) Patent Application Publication
(10) Pub. No.: US 2023/0413580 A1
(43) Pub. Date: Dec. 21, 2023

(54) SELECTOR DEVICE AND SEMICONDUCTOR DEVICE INCLUDING THE SAME

(71) Applicant: SK hynix Inc., Icheon-si (KR)

(72) Inventor: Gwang Hyuk SHIN, Icheon-si (KR)

(21) Appl. No.: 18/178,389

(22) Filed: Mar. 3, 2023

(30) Foreign Application Priority Data
Jun. 17, 2022 (KR) 10-2022-0074256

(51) Int. Cl. H10B 63/00; H10B 61/00

(52) U.S. Cl. CPC H10B 63/24; H10B 61/10; H10B 63/80

(57) ABSTRACT

A selector device may include: a first electrode layer; a second electrode layer disposed to be spaced apart from the first electrode layer; a selector layer disposed between the first electrode layer and the second electrode layer and configured to perform a threshold switching operation by trapping conductive carriers or releasing trapped conductive carriers depending on an external voltage applied to the selector layer; and one or more barrier layers disposed between the first electrode layer and the selector layer, or between the selector layer and the second electrode layer, or both between the first electrode layer and the selector layer and between the selector layer and the second electrode layer, wherein at least one of the one or more barrier layers includes a two-dimensional layered material.

### PRIORITY CLAIM AND CROSS-REFERENCE TO RELATED APPLICATION

This patent document claims the priority and benefits of Korean Patent Application No. 10-2022-0074256 filed on Jun. 17, 2022, which is incorporated herein by reference in its entirety.

### TECHNICAL FIELD

This patent document relates to memory circuits or devices and their applications in semiconductor devices or systems.

### BACKGROUND

The recent trend toward miniaturization, low power consumption, high performance, and multi-functionality in the electrical and electronics industry has compelled the semiconductor manufacturers to focus on high-performance, high capacity semiconductor devices. Examples of such high-performance, high capacity semiconductor devices include memory devices that can store data by switching between different resistance states according to an applied voltage or current. The semiconductor devices may include an RRAM (resistive random access memory), a PRAM (phase change random access memory), an FRAM (ferroelectric random access memory), an MRAM (magnetic random access memory), and an electronic fuse (E-fuse).

### SUMMARY

The disclosed technology in this patent document relates to memory circuits or devices and their applications in semiconductor devices or systems. Various implementations of a semiconductor device can improve the performance of a semiconductor device and reduce manufacturing defects.

In one aspect, a selector device for implementing the disclosed technology may include: a first electrode layer; a second electrode layer disposed to be spaced apart from the first electrode layer; a selector layer disposed between the first electrode layer and the second electrode layer and configured to perform a threshold switching operation by trapping conductive carriers or releasing trapped conductive carriers depending on an external voltage applied to the selector layer; and one or more barrier layers disposed between the first electrode layer and the selector layer, or between the selector layer and the second electrode layer, or both between the first electrode layer and the selector layer and between the selector layer and the second electrode layer, wherein at least one of the one or more barrier layers includes a two-dimensional layered material.

In another aspect, a semiconductor device for implementing the disclosed technology may include: a first electrode layer; a second electrode layer disposed over the first electrode layer to be spaced apart from the first electrode layer; a selector layer disposed between the first electrode layer and the second electrode layer and configured to perform a threshold switching operation by trapping conductive carriers or releasing trapped conductive carriers depending on an external voltage applied to the selector layer; a memory layer disposed under the first electrode layer or over the second electrode layer to be connected in series with the selector layer such that the selector layer is operated to switch on or off an electrical path to the memory layer; and one or more barrier layers disposed between the first electrode layer and the selector layer, or between the selector layer and the second electrode layer, or both between the first electrode layer and the selector layer and between the selector layer and the second electrode layer, wherein at least one of the one or more barrier layers includes a two-dimensional layered material.

The above and other aspects of the disclosed technology are disclosed in the drawings, the detailed description and the claims.

### BRIEF DESCRIPTION OF THE DRAWINGS

FIGS. 1 to 3 illustrate an example of a selector device based on some implementations of the disclosed technology.

FIGS. 4A and 4B are illustrate an example of a semiconductor device based on some implementations of the disclosed technology.

FIGS. 5A to 5E are cross-sectional views illustrating an example method for fabricating a semiconductor device based on some implementations of the disclosed technology.

FIGS. 6A to 6D are cross-sectional views illustrating an example method for forming a material layer for a barrier layer based on some implementations of the disclosed technology.

FIG. 7 illustrates another example of a semiconductor device based on some implementations of the disclosed technology.

### DETAILED DESCRIPTION

Hereinafter, various embodiments of the disclosure will be described in detail with reference to the accompanying drawings.

The drawings are not necessarily drawn to scale. In some instances, proportions of at least some structures in the drawings may have been exaggerated in order to clearly illustrate certain features of the described embodiments. In presenting a specific example in a drawing or description having two or more layers in a multi-layer structure, the relative positioning relationship of such layers or the sequence of arranging the layers as shown reflects a particular implementation for the described or illustrated example and a different relative positioning relationship or sequence of arranging the layers may be possible. In addition, a described or illustrated example of a multi-layer structure might not reflect all layers present in that particular multilayer structure (e.g., one or more additional layers may be present between two illustrated layers). As a specific example, when a first layer in a described or illustrated multi-layer structure is referred to as being “on” or “over” a second layer or “on” or “over” a substrate, the first layer may be directly formed on the second layer or the substrate but may also represent a structure where one or more other intermediate layers may exist between the first layer and the second layer or the substrate.

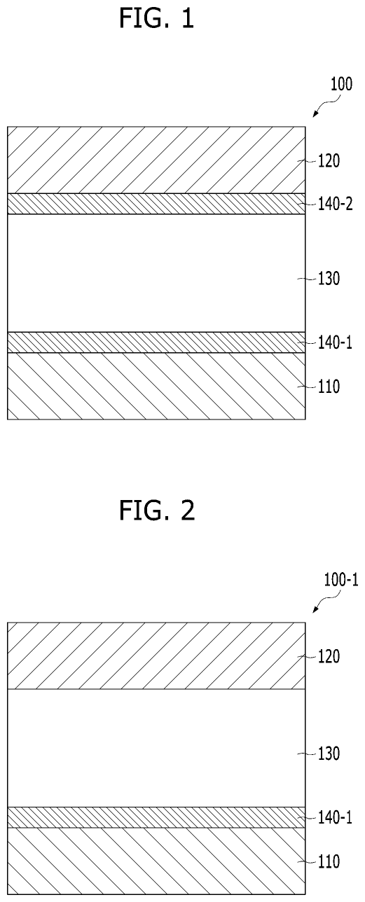

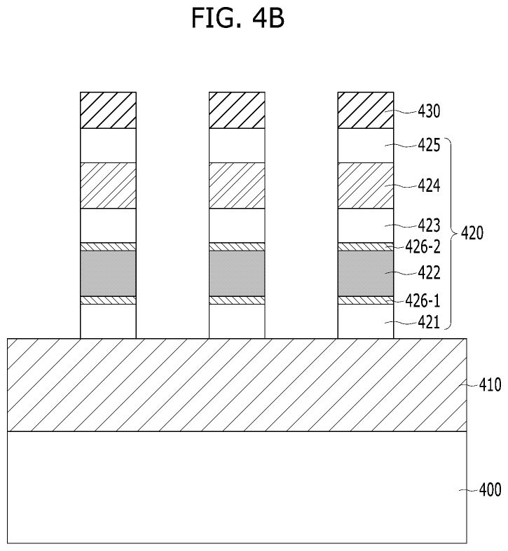

FIGS. 1 to 3 illustrate an example of a selector device based on some implementations of the disclosed technology. This selector device includes a selector layer 130 that can be controlled by applying an external control signal (e.g., a voltage) to be in either an electrically conductive state (“on” state) or an electrically less-conductive state or electrically non-conductive sate (“off” state) depending on whether the applied voltage is above or below a threshold voltage. This selector device can be used to turn on or turn off an electrical path for various applications, including, e.g., selecting or de-selecting a circuit as further explained below in connection with the semiconductor device in FIGS. 4A and 4B.

Referring to FIG. 1, the selector device 100 may include a first electrode layer 110, a second electrode layer 120, a selector layer 130 disposed between the first electrode layer 110 and the second electrode layer 120, a first barrier layer 140-1 disposed between the first electrode layer 110 and the selector layer 130 and a second barrier layer 140-2 disposed between the selector layer 130 and the second electrode layer 120.

The first electrode layer 110 and the second electrode layer 120 may include a single-layered structure or a multi-layered structure including various conductive materials such as a metal, a metal nitride, a conductive carbon material, or a combination thereof, respectively. For example, the first electrode layer 110 and the second electrode layer 120 may include tungsten (W), titanium (Ti), tantalum (Ta), platinum (Pt), aluminum (Al), copper (Cu), zinc (Zn), nickel (Ni), cobalt (Co), lead (Pb), tungsten nitride (WN), tungsten silicide (WSi), titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), carbon (C), silicon carbide (SiC), or silicon carbon nitride (SiCN), or a combination thereof.

The first electrode layer 110 and the second electrode layer 120 may include the same material as each other or different materials from each other.

The first electrode layer 110 and the second electrode layer 120 may have the same thickness as each other or different thicknesses from each other.

The selector layer 130 may serve to reduce or suppress a current leakage between memory elements of a semiconductor device. To this end, the selector layer 130 may exhibit threshold switching behavior that blocks or substantially limits a current when a magnitude of an applied voltage is less than a predetermined threshold value and allows the current to increase rapidly when the magnitude of the applied voltage is equal to or greater than the predetermined threshold value. This threshold value may be referred to as a threshold voltage, and the selector layer 130 may controlled to be in either a turned-on or “on” state to be electrically conductive or a turned-off or “off” state to be electrically less-conductive than the “on” state or electrically non-conductive depending on whether the applied voltage is above or below the threshold voltage. Thus, the selector layer 130 may have different electrically conductive states and exhibit switching between the different electrically conductive states by controlling the applied voltage relative to the threshold voltage.

The selector layer 130 may perform a threshold switching operation by trapping conductive carriers or releasing trapped conductive carriers (“detrapping”) at trap sites in the selector layer 130. The trap sites may capture or trap conductive carriers or release or detrap trapped conductive carriers to provide a path for the trapped conductive carriers to move again within the selector layer 130. When the magnitude of the applied voltage is equal to or greater than the predetermined threshold value, the conductive carriers are captured by the trap sites and move in the selector layer 130 to carry electric charge, and thus the selector layer 130 may be turned on to be electrically conductive. When the magnitude of the applied voltage decreases below the predetermined threshold value, the conductive carriers are detrapped from the trap sites and do not move in the selector layer 130, and thus the selector layer 130 may be turned off to be electrically non-conductive. In some implementations, the trap sites may be inherent in metal oxides or generated by doping impurities. In some implementations, the trap sites may be enhanced by further performing doping or other processes.

In some implementations, the selector layer 130 may include a dielectric material including a combination of dopants. The selector layer 130 may include an oxide with dopants, a nitride with dopants, or an oxynitride with dopants, or a combination thereof such as silicon oxide, titanium oxide, aluminum oxide, tungsten oxide, hafnium oxide, tantalum oxide, niobium oxide, silicon nitride, titanium nitride, aluminum nitride, tungsten nitride, hafnium nitride, tantalum nitride, niobium nitride, silicon oxynitride, titanium oxynitride, aluminum oxynitride, tungsten oxynitride, hafnium oxynitride, tantalum oxynitride, or niobium oxynitride, or a combination thereof. In some implementations, the selector layer 130 may include an oxide. For example, the selector layer 130 may include SiO₂, NbOₓ, TiO₂, VOₓ, WOₓ, ZrO₂(Y₂O₃), Bi₂O₃—BaO, (La₂O₃)ₓ(CeO₂)₁₋ₓ, Al₂O₃, HfO₂, or a combination thereof.

The selector layer 130 may further include a dopant. The dopants doped into the selector layer 130 may include an n-type dopant or a p-type dopant and be incorporated for example, by ion implantation process. Examples of the dopants may include one or more of boron (B), nitrogen (N), carbon (C), phosphorous (P), arsenic (As), aluminum (Al), silicon (Si) or germanium (Ge). For example, the selector layer 130 may include As-doped silicon oxide or Ge-doped silicon oxide.

An oxide such as a silicon oxide or a metal oxide included in the selector layer 130 may have defects resulting from a process for forming the oxide. These defects may form trap sites in the oxide. Moreover, the dopant may form or enhance the trap sites in the oxide. Such trap sites may cause the oxide to exhibit threshold switching behavior by trapping or detrapping the conductive carriers in the oxide depending on an external voltage applied to the selector layer 130.

In some implementations, a selector implemented based on an insulating material such as a metal oxide, material included in electrodes may react with oxygen included in the selector to form a material layer such as an interfacial oxide layer at an interface between the selector and the electrode. For example, when the selector includes As-doped SiO₂ and the electrode includes TiN, the interfacial oxide layer including TiOₓN_{y} may be formed at an interface between the selector and the electrode. A thickness of the interfacial oxide layer may vary depending on a metal-oxide formation energy. The interfacial oxide layer may deteriorate a threshold voltage (Vth) and a hold voltage (Vhold), thereby decreasing the operation reliability of the selector.

In order to overcome these problems, in implementations of the disclosed technology, the first barrier layer 140-1 may be formed between the selector layer 130 and the first electrode layer 110, and in addition to or instead of the first barrier layer 140-1, the second barrier layer 140-2 may be formed between the selector layer 130 and the second electrode layer 120. The first barrier layer 140-1 and the second barrier layer 140-2 may serve to prevent formation of an interfacial oxide layer between the selector layer 130 and the first electrode layer 110, and between the selector layer 130 and the second electrode layer 120, respectively. That is, diffusion of materials between the first electrode layer 110 or the second electrode layer 120 and the selector layer 130 and a reaction between the materials with oxygen included in the selector layer may be suppressed by the first and second barrier layers 140-1 and 140-2, thereby preventing formation of an interfacial oxide layer at an interface between the selector layer 130 and the first electrode layer 110, and between the selector layer 130 and the second electrode layer 120. Therefore, it is possible to prevent, reduce or minimize the deterioration of a threshold voltage (Vth) and a hold voltage (Vhold) of the selector device 100 caused by the interfacial oxide layer. As a result, the operation reliability of the selector device 100 can be improved. Further, it is possible to increase charge injection efficiency and reduce a hold current (Ihold).

In some implementations, either one of the first barrier layer 140-1 or the second barrier layer 140-2 may include two-dimensional layered materials (2DLMs).

In some implementations, both the first barrier layer 140-1 and the second barrier layer 140-2 may include two-dimensional layered materials (2DLMs).

Crystalline compounds may be classified into zero-dimensional (0D) materials, one-dimensional (1D) materials, two-dimensional (2D) materials and three-dimensional (3D) materials. Even if certain materials include the same elements as each other, when the dimensions or arrangements of the materials are different from each other, bonding characteristics between atoms become different, and thus physical properties such as mechanical strength and electron mobility may be changed.

Among these materials, two-dimensional layered materials may be referred to as a crystalline material consisting of a single layer of atoms. There are various types of the two-dimensional layered materials depending on the constituent elements. For example, the two-dimensional layered materials may be classified into a graphene-based material, a two-dimensional chalcogenide-based material, a two-dimensional oxide-based material and a phosphorous-based material.

Examples of the graphene-based two-dimensional layered materials may include graphene, fluorographene, graphene oxide, hexagonal boron nitride (hBN), BCN and others.

Examples of the two-dimensional chalcogenide-based two-dimensional layered materials may include transition metal dichalcogenide (TMD), transition metal trichalcogenide (TMT), metal phosphrous trichalcogenide (MPT), metal monochalcogenide (MMC) and others. Examples of the TMD may include MoS₂, WS₂, MoSe₂, WSe₂, MoTe₂, ZrS₂, ZrSe₂ and others, examples of the TMT may include TiS₃, TiSe₃, ZrS₃, ZrSe₃ and others, examples of the MPT may include MnPS₃, FePS₃, CoPS₃, NiPS₃ and others, and examples of the MMC may include GaS, GeSe, InSe and others.

Examples of the two-dimensional oxide-based two-dimensional layered materials may include MoO₃, WO₃, TiO₂, MnO₂, V₂O₅, TaO₃, RuO₂ and others.

Examples of the phosphorous-based two-dimensional layered materials may include black phosphorus (BP), phosphorene and others.

In some implementations, the first barrier layer 140-1 and/or the second barrier layer 140-2 may include the graphene-based, the two-dimensional chalcogenide-based, the two-dimensional oxide-based, the phosphorous-based two-dimensional layered materials, or a combination thereof. In some implementations, the first barrier layer 140-1 and/or the second barrier layer 140-2 may the two-dimensional layered materials including graphene, black phosphorus (BP), transition metal dichalcogenide (TMD), hexagonal boron nitride (hBN) or a combination thereof. The two-dimensional layered materials can form a very thin film and have high impermeability. Therefore, the first barrier layer 140-1 and/or the second barrier layer 140-2 including the two-dimensional layered materials can serve to prevent material diffusion between the first electrode layer 110 and the selector layer 130, and between the selector layer 130 and the second electrode layer 120, respectively.

Among the two-dimensional layered materials, graphene having semi-metal properties and black phosphorus (BP) having semiconductor properties are known as materials composed of a single element. As materials composed of heterogeneous elements, hexagonal boron nitride (hBN) having insulator properties and transition metal dichalcogenide (TMD) having metal, semiconductor or superconductor properties. These materials will be described in detail below.

Graphene is an allotrope of carbon consisting of a single layer of atoms arranged in a two-dimensional honeycomb lattice nanostructure. Graphene is a single layer (monolayer) of carbon atoms, tightly bound in a hexagonal honeycomb lattice. Graphene includes a stable structure with high physical and chemical stability. Further, graphene has very high malleability, high electron mobility, low resistance, high thermal conductivity, excellent impermeability, high Young's Modulus and a large specific surface area. Graphene with these characteristics has been applied as a key material to various industries such as displays, secondary batteries, solar cells, automobiles and lighting. For example, an organic light emitting electrode (OLED) including an anode formed of graphene shows electrical properties of graphene.

Further, graphene has an atomically thin hexagonal structure, and, in some implementations, one graphene layer may have a thickness of about 0.3 nm. Covalent bonds in a horizontal direction and Van der Waals bonds in a vertical direction allow graphene to have low surface roughness. Moreover, graphene includes an inert surface and can effectively block diffusion of very small gas molecules.

Black phosphorus (BP) has a puckered honeycomb structure in which a hexagonal structure of graphene is bent into a chair shape. Black phosphorus (BP) has semiconductor properties. In particular, Black phosphorus (BP) may have a suitable band-gap energy between graphene's band-gap energy 0 eV and TMD's band-gap energy 1.4-2.0 eV. Monolayer black phosphorus may have a band-gap energy of about 1.6-2.0 eV and the band-gap energy may be decreased by increasing the number of layers. Trilayer black phosphorus may have a band-gap energy of about 0.5-1.2 eV and bulk black phosphorus may have a band-gap energy of about 0.34 eV. There are two different directions at the black phosphorus edge, armchair and zigzag in the puckered honeycomb structure of black phosphorous. These distinctive directions create anisotropy in black phosphorus.

Transition metal dichalcogenide (TMD) may be referred to as a compound in which a transition metal (M) single element layer is inserted between two chalcogen elements (X) layers and have the formula of MX₂. For example, the transition metal (M) may include molybdenum (Mo), tungsten (W), vanadium (V), titanium (Ti), hafnium (Hf), zirconium (Zr) and others and the chalcogen element (X) may include sulfur (S), selenium (Se), tellurium (Te) and others, but examples of the transition metal (M) and the chalcogen element (X) are not limited thereto. For example, transition metal dichalcogenide (TMD) may include MoS₂, WS₂, MoSe₂, WSe₂, MoTe₂, ZrS₂, ZrSe₂and others. Transition metal dichalcogenide (TMD) may have various properties such as metal properties, semiconductor properties, superconductor properties, or magnetic material properties depending on the combination of the transition metal and the chalcogen element.

Transition metal dichalcogenide (TMD) may have a hexagonal honeycomb structure without inversion symmetry unlike graphene. Transition metal dichalcogenide (TMD) has a strong bond on the same plane but has a weak van der Waals bond between the layers. Thus, it may be easy to separate layers from each other and physical characteristics may vary depending on the number of atomic layers. For example, as the number of atomic layers decreases, a band-gap energy may increase. Since no dangling bonds exist on the surface of two-dimensional TMD, heterojunction structures can be arbitrarily created even between materials that are crystallographically or physically different from each other.

Hexagonal boron nitride (hBN) may have a hexagonal crystal structure similar to graphene, except that nitrogen and boron atoms exist at the position of carbon atoms. Hexagonal boron nitride (hBN) may exhibit a band-gap energy of about 6 eV. Hexagonal boron nitride (hBN) is physically and chemically very stable. Hexagonal boron nitride (hBN) is transparent and flexible and has excellent mechanical strength like graphene. Hexagonal boron nitride (hBN) has high thermal conductivity due to weak electron-phonon interaction.

The two-dimensional layered materials may be formed by a mechanical peeling process, a chemical peeling process, a deposition process, an epitaxial growth process and others. Since the two-dimensional layered materials has a weak van der Waals bond between layers, it may be synthesized by a mechanical peeling process using an adhesive tape or a polydimethylsiloxane (PDMS) stamp or a chemical peeling process using a chemical solution. Further, for uniform large-area synthesis, a deposition process such as chemical vapor deposition (CVD) or atomic layer deposition (ALD) may be used. Processes for synthesizing the two-dimensional layered materials are performed using an appropriate process.

In some implementations, the two-dimensional layered materials included in the first barrier layer 140-1 and/or second barrier layer 140-2 may have a monolayer or multilayer structure. In some implementations, the word “monolayer” may be used to indicate a thin film with atomic thickness.

In some implementations, the first barrier layer 140-1 and the second barrier layer 140-2 may include the same material as each other, or different materials from each other.

In some implementations, the first barrier layer 140-1 and the second barrier layer 140-2 may have the same thickness as each other, or different thicknesses from each other.

In some implementations, since the selector device 100 includes the barrier layers 140-1 and 140-2 including the two-dimensional layered materials between the selector layer 130 and the first electrode layer 110, and between the selector layer 130 and the second electrode layer 120, diffusion of materials between the first electrode layer 110 or the second electrode layer 120 and the selector layer 130 and a reaction between the materials with oxygen included in the selector layer 130 can be suppressed, thereby preventing formation of an interfacial oxide layer. Therefore, it is possible to improve the deterioration of a threshold voltage (Vth) and a hold voltage (Vhold) caused by the interfacial oxide layer. As a result, the operation reliability of the selector device 100 can be improved. Further, it is possible to increase charge injection efficiency and reduce a hold current (Ihold).

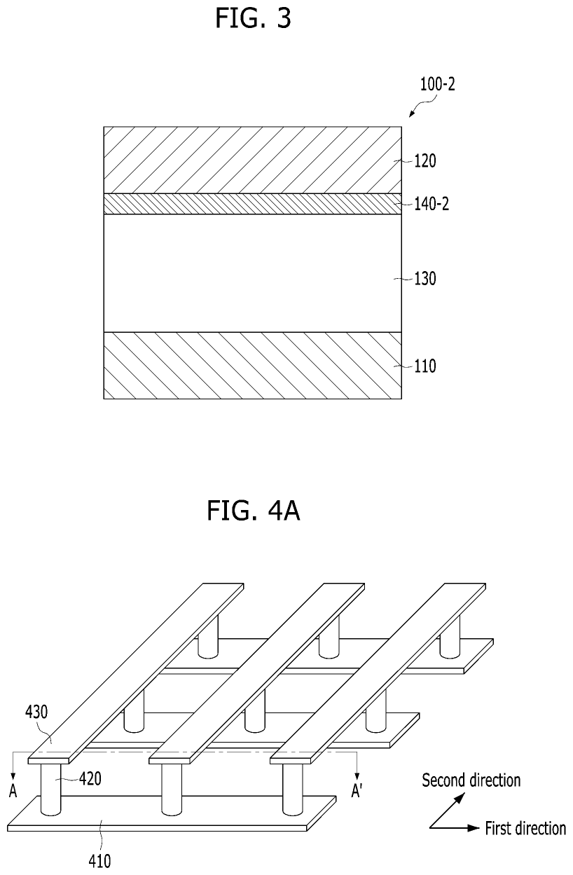

The selector device 100 shown in FIG. 1 includes the two barrier layers 140-1 and 140-2 between the selector layer 130 and the first electrode layer 110 and between the selector layer 130 and the second electrode layer 120. In another implementation, a selector device may include only one barrier layer. This will be described with reference to FIGS. 2 and 3.

FIGS. 2 and 3 illustrate an example of a selector device based on some implementations of the disclosed technology. The detailed descriptions similar to those described in the implementation shown in FIG. 1 will be omitted.

Referring to FIG. 2, a selector device 100-1 may include a first electrode layer 110, a second electrode layer 120, a selector layer 130 disposed between the first electrode layer 110 and the second electrode layer 120 and a first barrier layer 140-1 disposed between the selector layer 130 and the first electrode layer 110. Different from the selector device 100 shown in FIG. 1, the selector device 100-1 does not include the second barrier layer 140-2 between the selector layer 130 and the second electrode layer 120.

The first barrier layer 140-1 may include two-dimensional layered materials. For example, the two-dimensional layered materials may include a graphene-based, a two-dimensional chalcogenide-based, a two-dimensional oxide-based, a phosphorous-based two-dimensional layered materials, or a combination thereof. In some implementations, the two-dimensional layered materials included in the first barrier layer 140-1 may include graphene, black phosphorus (BP), transition metal dichalcogenide (TMD), hexagonal boron nitride (hBN) or a combination thereof. The two-dimensional layered materials can form a very thin film and have high impermeability so as to function as a blocking layer for preventing material diffusion.

In some implementations, since the selector device 100-1 includes the first barrier layer 140-1, which includes the two-dimensional layered materials between the selector layer 130 and the first electrode layer 110, diffusion of materials between the first electrode layer 110 and the selector layer 130 and a reaction between the materials with oxygen included in the selector layer 130 can be suppressed, thereby preventing formation of an interfacial oxide layer.

Referring to FIG. 3, a selector device 100-2 may include a first electrode layer 110, a second electrode layer 120, a selector layer 130 disposed between the first electrode layer 110 and the second electrode layer 120 and a second barrier layer 140-2 disposed between the selector layer 130 and the second electrode layer 120. Different from the selector device 100 shown in FIG. 1, the selector device 100-2 does not include the first barrier layer 140-1 disposed between the selector layer 130 and the first electrode layer 110.

The second barrier layer 140-2 may include two-dimensional layered materials. For example, the two-dimensional layered materials may include a graphene-based, a two-dimensional chalcogenide-based, a two-dimensional oxide-based, a phosphorous-based two-dimensional layered materials, or a combination thereof. In some implementations, the two-dimensional layered materials included in the first barrier layer 140-1 may include graphene, black phosphorus (BP), transition metal dichalcogenide (TMD), hexagonal boron nitride (hBN) or a combination thereof. The two-dimensional layered materials can form a very thin film and have high impermeability so as to function as a blocking layer for preventing material diffusion.

In some implementations, since the selector device 100-2 includes the second barrier layer 140-2, which includes the two-dimensional layered materials between the selector layer 130 and the second electrode layer 120, diffusion of materials between the second electrode layer 120 and the selector layer 130 and a reaction between the materials with oxygen included in the selector layer 130 can be suppressed, thereby preventing formation of an interfacial oxide layer.

Each of the selector devices 100, 100-1 and 100-2 may be combined with a memory element to form a semiconductor device. This will be described with reference to FIGS. 4A and 4B. FIG. 4A is a perspective view, and FIG. 4B is a cross-sectional view taken along line A-A′ of FIG. 4A.

FIGS. 4A and 4B illustrate an example of a semiconductor device based on some implementations of the disclosed technology. The illustrated semiconductor device may include an array of cells 420 that are connected to first conductive lines 410 and first conductive lines 430 in a cross-point structure. Each cell 420 may include a selector device as part of the cell 420 to select that particular cell 420 to be connected to, or disconnected from, its corresponding intersecting first and second conductive lines 410 and 430. In this context, the selector device performs the operation of “selecting” or “de-selecting” the cell 420. In general, the cells 420 can be configured as desired cell circuits. In this example, each cell 420 is a memory cell circuit that stores data and performs the operations of writing data and reading data at the memory layer 424 as further explained below.

Referring to FIGS. 4A and 4B, the semiconductor device may include a cross-point structure including a substrate 400, first conductive lines 410 formed over the substrate 400 and extending in a first direction, second conductive lines 430 formed over the first conductive lines 410 to be spaced apart from the first conductive lines 410 and extending in a second direction crossing the first direction, and memory cells 420 disposed at intersections of the first conductive lines 410 and the second conductive lines 430 between the first conductive lines 410 and the second conductive lines 430, respectively. In this patent document, the conductive lines can indicate conductive structures that electrically connect two or more circuit elements in the semiconductor memory. In some implementations, the conductive lines include word lines that are used to control access to memory cells in the memory device and bit lines that are used to read out information stored in the memory cells. In some implementations, the conductive lines include interconnects that carry signals between different circuit elements in the semiconductor memory.

The substrate 400 may include a semiconductor material such as silicon. A required lower structure (not shown) may be formed in the substrate 400. For example, the substrate 400 may include a driving circuit (not shown) electrically connected to the first conductive lines 410 and/or the second conductive lines 430 to control operations of the memory cells 420. In some implementations, the conductive lines can indicate conductive structures that electrically connect two or more circuit elements in the semiconductor device. In some implementations, the conductive lines include word lines that are used to control access to memory cells in the memory device and bit lines that are used to read out information stored in the memory cells. In some implementations, the conductive lines include interconnects that carry signals between different circuit elements in the semiconductor device.

The first conductive lines 410 and the second conductive lines 430 may be connected to a lower end and an upper end of the memory cell 420, respectively, and may provide a voltage or a current to the memory cell 420 to drive the memory cell 420. When the first conductive lines 410 functions as a word line, the second conductive lines 430 may function as a bit line. Conversely, when the first conductive lines 410 functions as a bit line, the second conductive lines 430 may function as a word line. The first conductive lines 410 and the second conductive lines 430 may include a single-layered structure or a multi-layered structure including one or more of various conductive materials.

Examples of the conductive materials may include a metal, a metal nitride, or a conductive carbon material, or a combination thereof, but are not limited thereto. For example, the first conductive lines 410 and the second conductive lines 430 may include tungsten (W), titanium (Ti), tantalum (Ta), platinum (Pt), aluminum (Al), copper (Cu), zinc (Zn), nickel (Ni), cobalt (Co), lead (Pb), tungsten nitride (WN), tungsten silicide (WSi), titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), carbon (C), silicon carbide (SiC), or silicon carbon nitride (SiCN), or a combination thereof.

The memory cell 420 may be arranged in a matrix having rows and columns along the first direction and the second direction so as to overlap the intersection regions between the first conductive lines 410 and the second conductive lines 430. In an implementation, each of the memory cells 420 may have a size that is substantially equal to or smaller than that of the intersection region between each corresponding pair of the first conductive lines 410 and the second conductive lines 430. In another implementation, each of the memory cells 420 may have a size that is larger than that of the intersection region between each corresponding pair of the first conductive lines 410 and the second conductive lines 430.

In some implementations, the memory cell 420 may have a cylindrical shape, but the shape of the memory cell 420 is not limited thereto. In some implementations, the memory cell 420 may have a square pillar shape.

Spaces between the first conductive lines 410, the second conductive lines 430 and the memory cell 420 may be filled with an insulating material.

The memory cell 420 may include a stacked structure including a lower electrode layer 421, a first barrier layer 426-1, a selector layer 422, a second barrier layer 426-2, a middle electrode layer 423, a memory layer 424 and an upper electrode layer 425 which are sequentially stacked.

The lower electrode layer 421, the first barrier layer 426-1, the selector layer 422, the second barrier layer 426-2 and the middle electrode layer 423 show in FIG. 4B may correspond to the first electrode layer 110, the first barrier layer 140-1, the selector layer 130, the second barrier layer 140-2 and the second electrode layer 120 shown in FIG. 1. The detailed descriptions similar to those described in the implementations shown in FIG. 1 will be omitted.

The lower electrode layer 421 disposed at a lowermost portion of each of the memory cells 420. The lower electrode layer 421 may function as a circuit node that carries a current or applies a voltage between one of the first conductive lines 410 and the remaining portion (e.g., the elements 426-1, 422, 426-2, 423, 424 and 425) of each of the memory cells 420. The middle electrode layer 423 may be interposed between the selector layer 422 and the memory layer 424. The middle electrode layer 423 may electrically connect the selector layer 422 and the memory layer 424 to each other while physically isolating or separating the selector layer 422 and the memory layer 424 from each other. The upper electrode layer 425 may be disposed at an uppermost portion of the memory cell 420 and function as a transmission path of electrical signals such as a voltage or a current between a material layer in the memory cell 420 and one of the second conductive lines 430.

The lower electrode layer 421, the middle electrode layer 423 and the upper electrode layer 425 may include a single-layered structure or a multi-layered structure including various conductive materials such as a metal, a metal nitride, a conductive carbon material, or a combination thereof, respectively. For example, the lower electrode layer 421, the middle electrode layer 423 and the upper electrode layer 425 may include tungsten (W), titanium (Ti), tantalum (Ta), platinum (Pt), aluminum (Al), copper (Cu), zinc (Zn), nickel (Ni), cobalt (Co), lead (Pb), tungsten nitride (WN), tungsten silicide (WSi), titanium nitride (TiN), titanium silicon nitride (TiSiN), titanium aluminum nitride (TiAIN), tantalum nitride (TaN), tantalum silicon nitride (TaSiN), tantalum aluminum nitride (TaAlN), carbon (C), silicon carbide (SiC), or silicon carbon nitride (SiCN), or a combination thereof.

The lower electrode layer 421, the middle electrode layer 423 and the upper electrode layer 425 may include the same material as each other or different materials from each other.

The lower electrode layer 421, the middle electrode layer 423 and the upper electrode layer 425 may have the same thickness as each other or different thicknesses from each other.

At least one of the lower electrode layer 421, the middle electrode layer 423 and the upper electrode layer 425 may be omitted. In some implementations, when the lower electrode layer 421 is omitted, the first conductive lines 410 may perform the function of the lower electrode layer 421. In some implementations, when the upper electrode layer 425 is omitted, the second conductive lines 430 may perform the function of the upper electrode layer 425.

The selector layer 422 may serve to control access to the memory layer 424 and prevent a current leakage between the memory cells 420 sharing the first conductive lines 410 or the second conductive lines 420. To this end, the selector layer 422 may perform a threshold switching operation through electron trapping/detrapping mechanism. In some implementations, the selector layer 422 may include an insulating material and a dopant. For example, the selector layer 422 may include an oxide with dopants, a nitride with dopants, or an oxynitride with dopants, or a combination thereof. In some implementations, the selector layer 422 may include an oxide. For example, the selector layer 422 may include SiO₂, NbOₓ, TiO₂, VOₓ, WOₓ, ZrO₂(Y₂O₃), Bi₂O₃—BaO, (La₂O₃)ₓ(CeO₂)₁₋ₓ, Al₂O₃, HfO₂, or a combination thereof. The selector layer 422 may further include a dopant. Examples of the dopants may include one or more of boron (B), nitrogen (N), carbon (C), phosphorous (P), arsenic (As), aluminum (Al), silicon (Si) or germanium (Ge).

The first barrier layer 426-1 may be disposed between the selector layer 422 and the lower electrode layer 421. The first barrier layer 426-1 may prevent diffusion of material between the lower electrode layer 421 and the selector layer 422 and a reaction of the materials with an oxide included in the selector layer 422, thereby suppressing formation of an interfacial oxide layer at an interface between the selector layer 422 and the lower electrode layer 421.

The second barrier layer 426-2 may be disposed between the selector layer 422 and the middle electrode layer 423. The second barrier layer 426-2 may prevent diffusion of materials between the middle electrode layer 423 and the selector layer 422 and a reaction of the materials with an oxide included in the selector layer 422, thereby suppressing formation of an interfacial oxide layer at an interface between selector layer 422 and the middle electrode layer 423.

As such, through the first barrier layer 426-1 and the second barrier layer 426-2, it is possible to improve the deterioration of a threshold voltage (Vth) and a hold voltage (Vhold) of the selector layer 422 caused by the interfacial oxide layer. Further, it is possible to increase charge injection efficiency and reduce a hold current (Ihold).

Either one or both of the first barrier layer 426-1 and the second barrier layer 426-2 may include two-dimensional layered materials.

In some implementations, the two-dimensional layered materials included in the first barrier layer 426-1 and/or the second barrier layer 426-2 may include a graphene-based, a two-dimensional chalcogenide-based, a two-dimensional oxide-based, a phosphorous-based two-dimensional layered materials, or a combination thereof. In some implementations, the two-dimensional layered materials may include graphene, black phosphorus (BP), transition metal dichalcogenide (TMD), hexagonal boron nitride (hBN) or a combination thereof. The two-dimensional layered materials can form a very thin film and have high impermeability so that it can function as a blocking layer for preventing material diffusion between the lower electrode layer 421 and the selector layer 422, and between the selector layer 422 and the middle electrode layer 423.

In some implementations, the two-dimensional layered materials included in the first barrier layer 426-1 and/or the second barrier layer 426-2 may have a monolayer or multilayer structure. In some implementations, the word “monolayer” may be used to indicate a thin film with atomic thickness.

In some implementations, the first barrier layer 426-1 and the second barrier layer 426-2 may include the same material as each other, or different materials from each other.

In some implementations, the first barrier layer 426-1 and the second barrier layer 426-2 may have the same thickness as each other, or different thicknesses from each other.

The semiconductor device shown in FIGS. 4A and 4B includes the first barrier layer 426-1 and the second barrier layer 426-2. In another implementation, a semiconductor device may include only the first barrier layer 426-1 disposed between the lower electrode layer 421 and the selector layer 422. In another implementation, a semiconductor device may include only the second barrier layer 426-2 disposed between the selector layer 422 and the middle electrode layer 423.

The memory layer 424 may be used to store data by switching between different resistance states according to an applied voltage or current. The memory layer 424 may have a single-layered structure or a multi-layered structure including at least one of materials having a variable resistance characteristic used for an RRAM, a PRAM, an MRAM, an FRAM, and others. For example, the memory layer 424 may include a metal oxide such as a transition metal oxide or a perovskite-based oxide, a phase change material such as a chalcogenide-based material, a ferromagnetic material, a ferroelectric material, or others. In some implementations, the memory layer 424 may include a magnetic tunnel junction (MTJ) structure. However, the implementations are not limited thereto, and the memory cell 420 may include other memory layers capable of storing data in various ways instead of the memory layer 424.

In some implementations, each of the memory cells 420 includes the lower electrode layer 421, the first barrier layer 426-1, the selector layer 422, the second barrier layer 426-2, the middle electrode layer 423, the memory layer 424 and the upper electrode layer 425. The structures of the memory cells 420 may be varied without being limited to one as shown in FIGS. 4A and 4B as long as the memory cells 420 have data storage properties. In some implementations, at least one of the lower electrode layer 421, the middle electrode layer 423 and the upper electrode layer 425 may be omitted. In some implementations, the relative position of the selector layer 422 and the memory layer 424 may be reversed. In some implementations, in addition to the layers 421, 426-1, 422, 426-2, 423, 424 and 425 shown in FIG. 4B, the memory cells 420 may further include one or more layers (not shown) for enhancing characteristics of the memory cells 420 or improving fabricating processes.

In some implementations, neighboring memory cells of the plurality of memory cells 420 may be spaced apart from each other at a predetermined interval, and trenches may be present between the plurality of memory cells 420. A trench between neighboring memory cells 420 may have a height to width ratio (i.e., an aspect ratio) in a range from 1:1 to 40:1, from 10:1 to 40:1, from 10:1 to from 5:1 to 10:1, from 10:1 to 15:1, from 1:1 to 25:1, from 1:1 to 30:1, from 1:1 to 35:1, or from 1:1 to 45:1.

In some implementations, the trench may have sidewalls that are substantially perpendicular to an upper surface of the substrate 400. In some implementations, neighboring trenches may be spaced apart from each other by an equal or similar distance.

Although one cross-point structure has been described, two or more cross-point structures may be stacked in a vertical direction perpendicular to a top surface of the substrate 400.

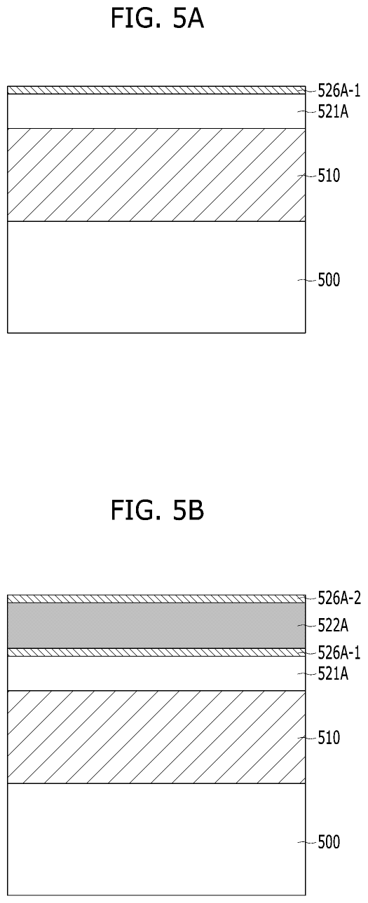

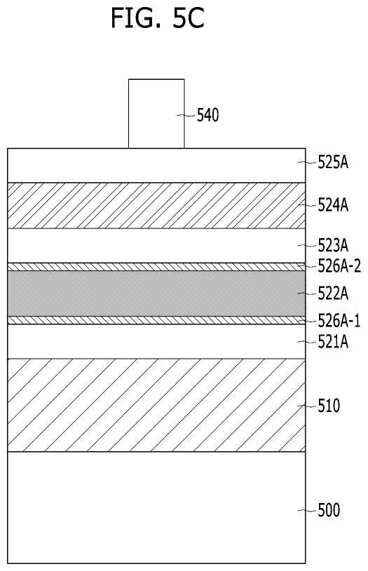

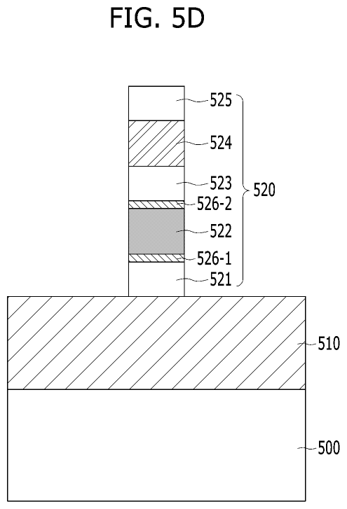

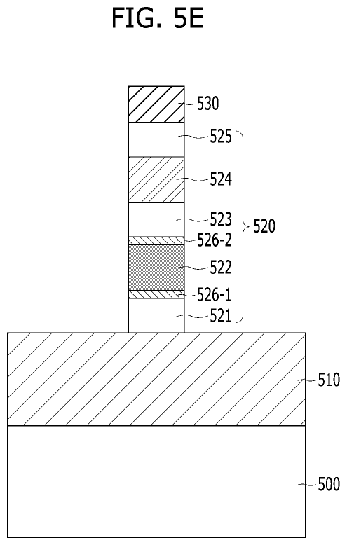

A method for fabricating a semiconductor device will be explained with reference to FIGS. 5A to 5E. The detailed descriptions similar to those described in FIGS. 1 to 3 and 4A and 4B will be omitted.

FIGS. 5A to 5E are cross-sectional views illustrating an example method for fabricating a semiconductor device based on some implementations of the disclosed technology.

Referring to FIG. 5A, first conductive lines 510 may be formed over a substrate 500 in which a predetermined structure is formed. For example, the first conductive lines 510 may be formed by forming a conductive layer for the first conductive lines 510 and etching the conductive layer using a mask pattern in a line shape extending in a first direction.

A material layer 521A for forming a lower electrode layer and a material layer 526A-1 for forming a first barrier layer may be sequentially formed over the first conductive lines 510.

The material layer 521A may have include a single-layered structure or a multi-layered structure including various conductive materials such as a metal, a metal nitride, a conductive carbon material, or a combination thereof.

The material layer 526A-1 may include two-dimensional layered materials. In some implementations, the two-dimensional layered materials may include a graphene-based, a two-dimensional chalcogenide-based, a two-dimensional oxide-based, a phosphorous-based two-dimensional layered materials, or a combination thereof. In some implementations, the two-dimensional layered materials may include graphene, black phosphorus (BP), transition metal dichalcogenide (TMD), hexagonal boron nitride (hBN) or a combination thereof.

In some implementations, an appropriate process may be used to synthesize the two-dimensional layered materials. For example, the two-dimensional layered materials may be formed by a mechanical peeling process, a chemical peeling process, a deposition process, an epitaxial growth process and others. Since the two-dimensional layered materials has a weak van der Waals bond between layers, it may be synthesized by a mechanical peeling process using an adhesive tape or a polydimethylsiloxane (PDMS) stamp or a chemical peeling process using a chemical solution. Further, for uniform large-area synthesis, a deposition process such as chemical vapor deposition (CVD) or atomic layer deposition (ALD) may be used.

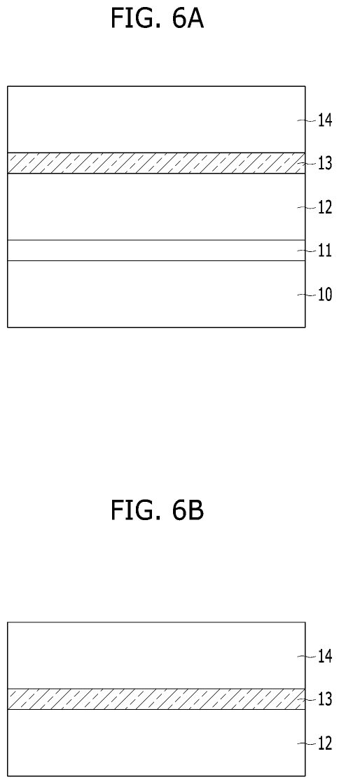

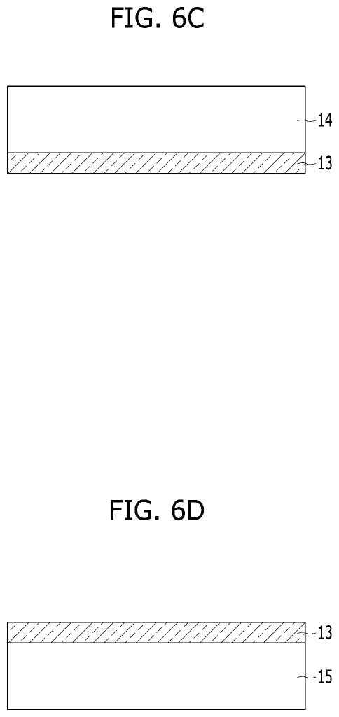

An example method for forming the material layer 526A-1 will be described with reference to FIGS. 6A to 6D.

FIGS. 6A to 6D are cross-sectional views illustrating an example method for forming a material layer for a barrier layer based on some implementations of the disclosed technology. In the implementation shown in FIGS. 6A to 6D, the method for forming the material layer for the barrier layer will be explained with respect to graphene as an example of the two-dimensional layered materials.

Referring to FIG. 6A, an insulating layer 11, a metal layer 12, a graphene layer 13 and a support layer 14 may be sequentially formed over an initial substrate 10.

The initial substrate 10 may include a semiconductor material, such as silicon.

The insulating layer 11 may include an oxide, a nitride, or a combination thereof. For example, the insulating layer 11 may include silicon oxide, aluminum oxide, or a combination thereof.

The metal layer 12 may have an excellent adsorption property to carbon and function as a catalyst for graphene synthesis. In some implementations, the metal layer 12 may include a transition metal having an excellent adsorption property to carbon. For example, the metal layer 12 may include nickel (Ni), copper (Cu), platinum (Pt), cobalt (Co), iridium (Ir), ruthenium (Ru), gold (Au), silver (Ag), germanium (Ge), iron (Fe), or a combination thereof.

The graphene layer 13 may be formed by chemical vapor deposition (CVD). For example, the initial substrate 10 on which the metal layer 12 and the insulating layer 11 are formed may be placed in a quartz tube and a temperature may be raised to about 1000° C. under an atmospheric pressure and H₂ gas atmosphere. Then, by treating the initial substrate 10 with a mixed gas of methane, hydrogen, helium, or the like, carbon atoms may be decomposed from the precursor methane. The decomposed carbon atoms may react with the metal layer 12 as a catalyst and an appropriate amount of carbon atoms may be dissolved in or adsorbed onto the metal layer 12. Subsequently, by cooling to room temperature, carbon atoms included in the metal layer 12 may be crystallized to form the graphene layer 13.

The graphene layer 13 may be formed using at least one of the commonly used chemical vapor deposition (CVD) methods.

The support layer 14 may serve to support the graphene layer 13 for the transfer of the graphene layer 13. The support layer 14 may include a polymer. For example, the support layer 14 may include poly(dimethylsiloxane) (PDMS), poly(methylmethacrylate) (PMMA), polycarbonate (PC), polyimide (PI), polystyrene (PS), polyethylene (PE), or a combination thereof.

In some implementations, the support layer 14 may be formed by bonding a solid polymer layer on the graphene layer 13 using a heat release tape or others.

In some implementations, the support layer 14 may be formed by coating a polymer solution on the graphene layer 13. The coating method used for forming support layer 14 may include spin coating, roll-to-roll coating, spin spray coating, spray coating, dip coating, bar coating, brush coating, or slit coating, but is not limited thereto.

Referring to FIG. 6B, the initial substrate 10 and the insulating layer 11 may be removed.

An operation for separating the initial substrate 10 and the insulating layer 11 from the metal layer 12, the graphene layer 13 and the support layer 14 may be performed, for example, by mechanically peeling the laminated structure of FIG. 4A in water.

Referring to FIG. 6C, the metal layer 12 may be removed.

An operation for separating the metal layer 12 from the graphene layer 13 and the support layer 14 may be performed by etching the metal layer 12. For example, the metal layer 12 may be removed by a chemical etch process. An etchant for etching the metal layer 12 may be appropriately selected depending on the metal layer 12. Examples of the etchant may include FeCl₃, but are not limited thereto.

Referring to FIG. 6D, the graphene layer 13 may be formed on a target substrate 15.

The target substrate 15 may be a substrate on which the graphene layer 13 is finally formed. In some implementations, the target substrate 15 may correspond to the material layer 222A of FIG. 2A. The graphene layer 13 may correspond to the material layer 223A.

In some implementations, the graphene layer 13 may be formed on the target substrate by transferring graphene to the target substrate. The graphene transfer for forming the graphene layer 13 may be performed by using at least one of the commonly used material transfer techniques. For example, the graphene transfer for forming the graphene layer 13 may be performed by bringing the target substrate 15 into contact with the graphene layer 13 and heating them.

Referring to FIGS. 6A to 6D, the graphene layer 13 may be formed by using chemical vapor deposition (CVD). In addition to the method in FIGS. 6A to 6D, various methods may be used for graphene transfer for forming the graphene layer 13. In some implementations, the graphene layer 13 may be formed by a chemical vapor deposition (CVD) process and/or a transfer process. In some implementations, the graphene layer 13 may be formed by, in addition to or in lieu of the chemical vapor deposition (CVD) process, a mechanical peeling process, an epitaxial growth process, a chemical peeling process, or others. In some implementations, the graphene layer 13 may be formed by a roll-to-roll synthesis. In the mechanical peeling process, graphene may be formed by peeling off one layer from a graphite crystal having a multilayer structure by mechanical force. For example, graphene may be formed by stacking graphite in layers on a substrate, performing a peeling process using a tape, and removing the remaining adhesive component through heat treatment in a reducing atmosphere.

In the epitaxial growth process, graphene may be formed by performing a heat treatment on a material having carbon such as silicon carbide (SiC) under a high temperature of about 1500° C. During the heat treatment, carbon grows along grains of a surface of SiC to form graphene.

The chemical peeling process may be performed to form graphene by using a redox property of graphite. In the chemical peeling process, graphene may be formed by forming graphite oxide by oxidizing graphite using a strong acid, an oxidizing agent or others, bringing graphite oxide into contact with water, allowing water molecules to penetrate spaces between layers of graphite oxide, which results from the high hydrophilicity of graphite oxide, forming a graphene oxide sheet by using a ultrasonic grinder after the interlayer spaces is widened by the water molecules, and removing impurities by a reduction process.

In the roll-to-roll synthesis, a deposition process, a printing process, a peeling process, an etch process and a transfer process are performed sequentially or continuously. For example, in the roll-to-roll synthesis, graphene may be formed by growing graphene on a copper substrate by CVD, attaching graphene to a polymer film having an adhesive by passing between two rollers, removing the copper substrate, removing adhesive between graphene and the polymer film, and transferring graphene to a final substrate.

In the implementation shown in FIGS. 6A to 6D, the method has been described for graphene as the two-dimensional layered materials. However, when another two-dimensional layered material other than graphene are used, the material layer for forming the barrier layer may be formed by a similar method or any other synthesis method. For example, the two-dimensional layered materials may be synthesized by a mechanical peeling process, a chemical peeling process, a deposition process, an epitaxial growth process and others.

Returning to FIG. 5B, material layer 526A-1 including the two-dimensional layered materials may be formed over the material layer 521A, for example, by the processes described in FIGS. 6A to 6D.

The material layer 526A-1 may include two-dimensional layered materials having a monolayer or multilayer structure.

Referring to FIG. 5C, a material layer 522A for forming a selector layer and a material layer 526A-2 for forming a second barrier layer may be sequentially formed over the material layer 526A-1.

The material layer 522A may include an insulating material and a dopant so as to perform a threshold switching operation through electron trapping/detrapping mechanism. For example, the material layer 522A may include an oxide with dopants, a nitride with dopants, or an oxynitride with dopants, or a combination thereof. In some implementations, the material layer 522A may include an oxide such as a metal oxide. For example, the material layer 522A may include SiO₂, NbOₓ, TiO₂, VOₓ, WOₓ, ZrO₂(Y₂O₃), Bi₂O₃—BaO, (La₂O₃)ₓ(CeO₂)₁₋ₓ, Al₂O₃, HfO₂, or a combination thereof. The material layer 522A may further include a dopant. Examples of the dopants may include one or more of boron (B), nitrogen (N), carbon (C), phosphorous (P), arsenic (As), aluminum (Al), silicon (Si) or germanium (Ge).

The material layer 526A-2 may include two-dimensional layered materials. In some implementations, the two-dimensional layered materials may include a graphene-based, a two-dimensional chalcogenide-based, a two-dimensional oxide-based, a phosphorous-based two-dimensional layered materials, or a combination thereof. In some implementations, two-dimensional layered materials may include graphene, black phosphorus (BP), transition metal dichalcogenide (TMD), hexagonal boron nitride (hBN) or a combination thereof.

The material layer 526A-2 may be formed by a process similar to the process for forming the material layer 526A-1. For example, when the material layer 526A-2 includes graphene, the material layer 526A-2 may be formed by the method shown in FIGS. 6A to 6D. In this case, the target substrate 15 shown in FIG. 6D may correspond to the material layer 522A and the graphene layer 13 shown in FIG. 6D may correspond to the material layer 526A-2. When the material layer 526A-2 includes another two-dimensional layered material other than graphene, the material layer 526A-2 may be formed by a similar method or by well-known synthesis methods. For example, the two-dimensional layered materials may be formed by a mechanical peeling process, a chemical peeling process, a deposition process, an epitaxial growth process and others.

The material layer 526A-2 may include a monolayer or a multilayer structure of the two-dimensional layered materials.

The material layer 526A-2 and the material layer 526A-1 may include the same material as each other, or different materials from each other.

Referring to FIG. 5C, a material layer 523A for forming a middle electrode layer, a material layer 524A for forming a memory layer, a material layer 525A for forming an upper electrode layer and a hard mask pattern 540 may be sequentially formed over the material layer 526A-2.

The material layer 523A and the material layer 525A may include a single-layered structure or a multi-layered structure including various conductive materials such as a metal, a metal nitride, a conductive carbon material, or a combination thereof, respectively.

The material layer 524A may have a single-layered structure or a multi-layered structure including at least one of materials having a variable resistance characteristic used for an RRAM, a PRAM, an MRAM, an FRAM, and others. The material layer 524A may include a metal oxide such as a transition metal oxide or a perovskite-based oxide, a phase change material such as a chalcogenide-based material, a ferromagnetic material, a ferroelectric material, or others. In some implementations, the material layer 524A may include a magnetic tunnel junction (MTJ) structure including a free layer having a variable magnetization direction, a pinned layer having a pinned magnetization direction and a tunnel barrier layer interposed between the free layer and the pinned layer.

The hard mask pattern 540 may include a material having excellent etch selectivity and hardness in order to improve a vertical profile of a memory cell 520. For example, the hard mask pattern 540 may include various metal materials, carbon, or a combination thereof.

The hard mask pattern 540 may be formed by forming a hard mask (not shown) on the material layer 525A, forming a photoresist pattern (not shown) on the hard mask, and etching the hard mask using the photoresist pattern as an etch barrier. Before forming the photoresist pattern, an anti-reflection layer (not shown) may be further formed on the hard mask in order to prevent reflection during an exposure process.

Referring to FIG. 5D, the memory cell 520 in which a lower electrode layer 521, a first barrier layer 526-1, a selector layer 522, a second barrier layer 526-2, a middle electrode layer 523, a memory layer 524 and an upper electrode layer 525 which are sequentially stacked may be formed by etching the material layer 525A, the material layer 524A, the material layer 523A, the material layer 526A-2, the material layer 522A, the material layer and the material layer 521A using the hard mask pattern 540 as an etch barrier.

In the implementation shown in FIG. 5D, the hard mask pattern 540 is removed. However, in another implementation, the hard mask pattern 540 may remain.

Referring to FIG. 5E, a second conductive lines 520 may be formed over the upper electrode layer 525.

In this way, a semiconductor device of FIG. 5E may be formed. The semiconductor device may include the first conductive lines 510, the memory cell 520 and the second conductive lines 530 which are sequentially formed over the substrate 500. The memory cell 520 may include the lower electrode layer 521, the first barrier layer 526-1, the selector layer 522, the second barrier layer 526-2, the middle electrode layer 523, the memory layer 524 and the upper electrode layer 525 which are sequentially stacked. The first barrier layer 526-1 may be formed between the lower electrode layer 521 and the selector layer 522 and the second barrier layer 526-2 may be formed between the selector layer 522 and the middle electrode layer 523. Either one or both of the first barrier layer 526-1 and the second barrier layer 526-2 may include the two-dimensional layered materials. The first barrier layer 526-1 and the second barrier layer 526-2 can prevent diffusion of materials between the lower electrode layer 521 and the selector layer 522, and between the selector layer 522 and the middle electrode layer 523, and a reaction of the materials with an oxygen included in the selector layer 522, thereby suppressing formation of an interfacial oxide layer. As a result, it is possible to improve the deterioration of a threshold voltage (Vth) and a hold voltage (Vhold) of the selector layer 522 caused by the interfacial oxide layer. Further, it is possible to increase charge injection efficiency and reduce a hold current (Ihold).

The first conductive lines 510, the memory cell 520, the lower electrode layer 521, the first barrier layer 526-1, the selector layer 522, the second barrier layer 526-2, the middle electrode layer 523, the memory layer 524, the upper electrode layer 525 and the second conductive lines 530 shown in FIG. 5E may correspond to the first conductive lines 410, the memory cell 420, the lower electrode layer 421, the first barrier layer 426-1, the selector layer 422, the second barrier layer 426-2, the middle electrode layer 423, the memory layer 424, the upper electrode layer 425 and the second conductive lines 430.

The semiconductor device shown in FIGS. 5A to 5E includes the first barrier layer 526-1 and the second barrier layer 526-2. However, in another implementation, the semiconductor device may include one barrier layer. In some implementations, a semiconductor device may include the first barrier layer 526-1 disposed between the lower electrode layer 521 and the selector layer 522. In some implementations, a semiconductor device may include the second barrier layer 526-2 disposed between the selector layer 522 and the middle electrode layer 523.

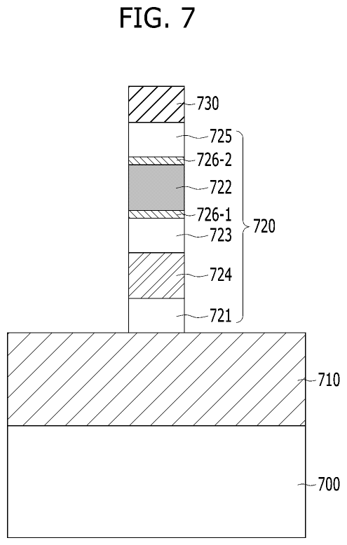

Further, the structure of the memory cell 520 may be varied without being limited to one as shown in FIGS. 5A to 5E as long as the memory cell 520 have data storage properties. In some implementations, the relative position of the selector layer 522 and the memory layer 524 may be reversed. This will be described with reference to FIG. 7.

FIG. 7 illustrates another example of a semiconductor device based on some implementations of the disclosed technology. Compared to the semiconductor devices shown in FIGS. 4A and 4B and 5A to 5E, there is a difference in that in the semiconductor device shown in FIG. 7, a memory layer 724 is formed under a selector layer 722, a first barrier layer 726-1 is formed between a middle electrode layer 723 and the selector layer 722 and a second barrier layer 726-2 is formed between the selector layer 722 and an upper electrode layer 725.

Referring to FIG. 7, the semiconductor memory may include a cross-point structure including a substrate 700, first conductive lines 710 formed over the substrate 700 and extending in a first direction, second conductive lines 730 formed over the first conductive lines 710 to be spaced apart from the first conductive lines 710 and extending in a second direction crossing the first direction, and memory cells 720 disposed at intersections of the first conductive lines 710 and the second conductive lines 730 between the first conductive lines 710 and the second conductive lines 430. The memory cell 720 may include a lower electrode layer 721, the memory layer 724, the middle electrode layer 723, the first barrier layer 726-1, the selector layer 722, the second barrier layer 726-2 and the upper electrode layer 725. One or more of the first barrier layer 726-1 and the second barrier layer 726-2 may include two-dimensional layered materials and prevent diffusion of materials between the middle electrode layer 723 and the selector layer 722, and between the selector layer 722 and the upper electrode layer 725 and a reaction of the materials with an oxygen included in the selector layer 722, thereby suppressing formation of an interfacial oxide layer. As a result, it is possible to improve the deterioration of a threshold voltage (Vth) and a hold voltage (Vhold) of the selector layer 722 caused by the interfacial oxide layer. Further, it is possible to increase charge injection efficiency and reduce a hold current (Ihold).

The semiconductor device shown in FIG. 7 includes two barrier layers, i.e., the first barrier layer 726-1 and the second barrier layer 726-2. However, in another implementation, the semiconductor device may include one barrier layer. In some implementations, a semiconductor device may include the first barrier layer 726-1 disposed between the middle electrode layer 723 and the selector layer 722. In some implementations, a semiconductor device may include the second barrier layer 726-2 disposed between the selector layer 722 and the upper electrode layer.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable sub combination. Moreover, although features may be described above as acting in certain combinations and even initially claimed as such, one or more features from a claimed combination can in some cases be excised from the combination, and the claimed combination may be directed to a sub combination or variation of a sub combination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few embodiments and examples are described. Enhancements and variations of the disclosed embodiments and other embodiments can be made based on what is described and illustrated in this patent document.

What is claimed is:

1. A selector device, comprising:
a first electrode layer;
a second electrode layer disposed to be spaced apart from the first electrode layer;
a selector layer disposed between the first electrode layer and the second electrode layer and configured to perform a threshold switching operation by trapping conductive carriers or releasing trapped conductive carriers depending on an external voltage applied to the selector layer; and
one or more barrier layers disposed between the first electrode layer and the selector layer, or between the selector layer and the second electrode layer, or both between the first electrode layer and the selector layer and between the selector layer and the second electrode layer,
wherein at least one of the one or more barrier layers includes a two-dimensional layered material.

2. The selector device according to claim 1, wherein the selector layer includes an oxide.

3. The selector device according to claim 2, wherein the oxide includes silicon oxide, metal oxide, or a combination of the silicon oxide and the metal oxide.

4. The selector device according to claim 2, wherein the selector layer includes a dopant doped into the oxide.

5. The selector device according to claim 1, wherein the two-dimensional layered material includes graphene-based two-dimensional layered materials, two-dimensional chalcogenide-based materials, two-dimensional oxide-based materials, phosphorous-based two-dimensional layered materials, or a combination of two or more of the graphene-based two-dimensional layered materials, the two-dimensional chalcogenide-based materials, the two-dimensional oxide-based materials, or the phosphorous-based two-dimensional layered materials.

6. The selector device according to claim 1, wherein the two-dimensional layered materials include graphene, black phosphorus (BP), transition metal dichalcogenide (TMD), hexagonal boron nitride (hBN) or a combination of two or more of the graphene, the BP, the TMD, or the hBN.

7. The selector device according to claim 1, wherein at least one of the one or more barrier layers includes a monolayer or a multilayer structure of the two-dimensional layered material.

8. A semiconductor device comprising:
a first electrode layer;
a second electrode layer disposed over the first electrode layer to be spaced apart from the first electrode layer;
a selector layer disposed between the first electrode layer and the second electrode layer and configured to perform a threshold switching operation by trapping conductive carriers or releasing trapped conductive carriers depending on an external voltage applied to the selector layer;
a memory layer disposed under the first electrode layer or over the second electrode layer to be connected in series with the selector layer such that the selector layer is operated to switch on or off an electrical path to the memory layer; and
one or more barrier layers disposed between the first electrode layer and the selector layer, or between the selector layer and the second electrode layer, or both between the first electrode layer and the selector layer and between the selector layer and the second electrode layer,
wherein at least one of the one or more barrier layers includes a two-dimensional layered material.

9. The semiconductor device according to claim 8, wherein the memory layer is disposed over the second electrode layer and the second electrode layer is configured to electrically connect the selector layer and the memory layer to each other while physically separating the selector layer and the memory layer from each other.

10. The semiconductor device according to claim 8, wherein the memory layer is disposed over the second electrode layer, and the semiconductor device further includes a third electrode layer disposed over the memory layer.

11. The semiconductor device according to claim 8, wherein the memory layer is disposed under the first electrode layer, and the first electrode layer is configured to electrically connect the selector layer and the memory layer to each other while physically separating the selector layer and the memory layer from each other.

12. The semiconductor device according to claim 8, wherein the memory layer is disposed under the first electrode layer and the semiconductor device further includes a third electrode layer disposed under the memory layer.

13. The semiconductor device according to claim 8, wherein the selector layer includes an oxide.

14. The semiconductor device according to claim 13, wherein the oxide includes silicon oxide, metal oxide, or a combination of the silicon oxide and the metal oxide.

15. The semiconductor device according to claim 13, wherein the selector layer includes a dopant doped into the oxide.

16. The semiconductor device according to claim 8, wherein the two-dimensional layered material includes graphene-based two-dimensional layered materials, two-dimensional chalcogenide-based materials, two-dimensional oxide-based materials, phosphorous-based two-dimensional layered materials, or a combination of two or more of the graphene-based two-dimensional layered materials, the two-dimensional chalcogenide-based materials, the two-dimensional oxide-based materials, or the phosphorous-based two-dimensional layered materials.

17. The semiconductor device according to claim 8, wherein the two-dimensional layered materials include graphene, black phosphorus (BP), transition metal dichalcogenide (TMD), hexagonal boron nitride (hBN) or a combination of two or more of the graphene, the BP, the TMD, or the hBN.

18. The semiconductor device according to claim 8, where at least one of the one or more barrier layers includes a monolayer or a multilayer structure of the two-dimensional layered material.

19. The semiconductor device according to claim 8 wherein the memory layer includes at least one of materials having a variable resistance characteristic used for a resistive random access memory (RRAM), a phase change random access memory (PRAM), a ferroelectric random access memory (FRAM) or a magnetic random access memory (MRAM).
